(19) United States
(12) Patent Application Publication
(10) Pub. No.: US 2024/0258985 A1
(43) Pub. Date: Aug. 1, 2024

(54) ACOUSTIC WAVE DEVICE AND MANUFACTURING METHOD OF ACOUSTIC WAVE DEVICE

(71) Applicant: Murata Manufacturing Co., Ltd., Nagaokakyo-shi (JP)

(72) Inventor: Kazunori INOUE, Nagaokakyo-shi (JP)

(21) Appl. No.: 18/611,810

(22) Filed: Mar. 21, 2024

Related U.S. Application Data
(63) Continuation of application No. PCT/JP2022/036805, filed on Sep. 30, 2022.
(60) Provisional application No. 63/250,633, filed on Sep. 30, 2021.

(51) Int. Cl. H03H 9/02; H03H 3/02; H03H 9/13; H03H 9/17

(52) U.S. Cl. CPC H03H 9/02015; H03H 3/02; H03H 9/131; H03H 9/173

(57) ABSTRACT

An acoustic wave device includes an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and an attenuator in at least a portion of the outer surface of the element substrate, except a surface of contact with the piezoelectric layer, and structured to attenuate unwanted emissions.

### CROSS REFERENCE TO RELATED APPLICATIONS

This application claims the benefit of priority to Provisional Application No. 63/250,633 filed on Sep. 30, 2021 and is a Continuation Application of PCT Application No. PCT/JP2022/036805 filed on Sep. 30, 2022. The entire contents of each application are hereby incorporated herein by reference.

### BACKGROUND OF THE INVENTION

### 1. Field of the Invention

The present disclosure relates to acoustic wave devices each including a piezoelectric layer.

### 2. Description of the Related Art

For example, Japanese Unexamined Patent Application Publication No. 2012-257019 discloses an acoustic wave device using plate waves. The acoustic wave device according to Japanese Unexamined Patent Application Publication No. 2012-257019 includes a support, a piezoelectric substrate, and an IDT electrode. The support is provided with an air gap. The piezoelectric substrate is provided on the support so as to overlap the air gap. The IDT electrode is provided on the piezoelectric substrate so as to overlap the air gap. In the acoustic wave device, the IDT electrode excites plate waves. The edge of the air gap does not include any straight portion extending in parallel to the propagation direction of plate waves excited by the IDT electrode.

In recent years, there has been demand for an acoustic wave device having high mechanical strength with unwanted emissions attenuated.

### SUMMARY OF THE INVENTION

Example embodiments of the present invention provide acoustic wave devices each with high mechanical strength and unwanted emissions that are attenuated.

An acoustic wave device according to an example embodiment of the present invention includes an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and an attenuator provided in at least a portion of an outer surface of the element substrate, except a surface of contact with the piezoelectric layer, and structured to attenuate unwanted emissions.

An acoustic wave device according to an example embodiment of the present invention includes an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and a different material portion provided in at least a portion of an outer surface of the element substrate, except a surface of contact with the piezoelectric layer, and is made of a material different from the element substrate.

An acoustic wave device according to an example embodiment of the present invention includes an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and an uneven portion provided in at least a portion of an outer surface of the element substrate, except a surface of contact with the piezoelectric layer, and including an uneven surface.

An acoustic wave device according to an example embodiment of the present invention includes an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and a low acoustic impedance portion provided in at least a portion of an outer surface of the element substrate, except a surface of contact with the piezoelectric layer, and including a low acoustic impedance layer.

A method of manufacturing an acoustic wave device according to an example embodiment of the present invention, the acoustic wave device including an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and an attenuator provided in at least a portion of an outer surface of the element substrate, except a surface of contact with the piezoelectric layer, and structured to attenuate unwanted emissions, the method including forming the attenuator within the element substrate by laser irradiation.

A method of manufacturing an acoustic wave device according to an example embodiment of the present invention, the acoustic wave device including an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and an attenuator provided in at least a portion of an outer surface of the element substrate, except a surface of contact with the piezoelectric layer, and structured to attenuate unwanted emissions, the method including forming the attenuator by performing chemical vapor deposition of a SiO₂ film.

A method of manufacturing an acoustic wave device according to an example embodiment of the present invention, the acoustic wave device including an acoustic wave element including an element substrate, a piezoelectric layer on the element substrate, a functional electrode on the piezoelectric layer, and a wiring electrode on the piezoelectric layer and electrically coupled to the functional electrode, the element substrate including an air gap at a position overlapping a portion of the functional electrode in plan view in a stacking direction of the element substrate and the piezoelectric layer, a mounting substrate including an external terminal, a metal bump coupling the wiring electrode and the external terminal, sealing resin sealing the acoustic wave element and the metal bump, and an attenuator provided in at least a portion of an outer surface of the element substrate, except a surface of contact with the piezoelectric layer, and structured to attenuate unwanted emissions, the method including in a process of flip-chip bonding the acoustic wave element that is singulated, onto the mounting substrate, providing the attenuator in, of a pair of major surfaces of the element substrate that are transverse to the stacking direction, another major surface that is opposite to one major surface close to the piezoelectric layer.

According to example embodiments of the present invention, it is possible to provide acoustic wave devices each with high mechanical strength and unwanted emissions that are attenuated, and manufacturing methods of such acoustic wave devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a schematic perspective view illustrating an acoustic wave element according to first and second example embodiments of the present invention.

FIG. 1B is a plan view illustrating an electrode structure on a piezoelectric layer according to the first and second example embodiments of the present invention.

FIG. 2 is a cross-sectional view along line A-A in FIG. 1A.

FIG. 3A is a schematic elevational cross-sectional view for explaining Lamb waves propagating in a piezoelectric film of an acoustic wave element in the related art.

FIG. 3B is a schematic elevational cross-sectional view for explaining waves in an acoustic wave element according to an example embodiment of the present invention.

FIG. 4 is a schematic diagram illustrating bulk waves when voltage is applied across a first electrode and a second electrode such that the potential of the second electrode is higher than that of the first electrode.

FIG. 5 is a diagram illustrating resonance characteristics of an acoustic wave element according to a first example embodiment of the present invention.

FIG. 6 is a diagram illustrating the relationship between d/2p and fractional bandwidth of an acoustic wave element as a resonator according to an example embodiment of the present invention.

FIG. 7 is a plan view of another acoustic wave element according to the first example embodiment of the present invention.

FIG. 8 is a reference diagram illustrating an example of resonance characteristics of an acoustic wave element according to an example embodiment of the present invention.

FIG. 9 is a diagram illustrating the relationship between the fractional bandwidth and the amount of phase rotation of spurious impedance, which is normalized by about 180 degrees, as the magnitude of spurious components, when many acoustic wave resonators are provided.

FIG. 10 is a diagram illustrating the relationship between d/2p, a metallization ratio MR, and a fractional bandwidth.

FIG. 11 is a diagram illustrating a fractional bandwidth map with respect to Euler angles (0°, θ, ψ) of LiNbO₃ when d/p is reduced infinitesimally close to zero.

FIG. 12 is a partially-cutaway perspective view for explaining an acoustic wave element according to the first example embodiment of the present invention.

FIG. 13 is a schematic elevational cross-sectional view illustrating an acoustic wave device of a second example embodiment of the present invention.

FIG. 14 is a schematic elevational cross-sectional view illustrating an example of an attenuator 170 of the acoustic wave device in FIG. 13.

FIG. 15 is a diagram for explaining a case where a large number of ripples produced inside or outside a filter pass band are superposed on an important portion of filter characteristics.

FIG. 16 is an enlarged view of a dotted portion in FIG. 15.

FIG. 17 is a first diagram for explaining occurrence of ripples.

FIG. 18 is a second diagram for explaining occurrence of ripples.

FIG. 19 is a third diagram for explaining occurrence of ripples.

FIG. 20 is a schematic elevational cross-sectional view illustrating a first modification of an acoustic wave device according to the second example embodiment of the present invention.

FIG. 21 is a first diagram for explaining a manufacturing method of the acoustic wave device in FIG. 20.

FIG. 22 is a second diagram for explaining the manufacturing method of the acoustic wave device in FIG. 20.

FIG. 23 is a third diagram for explaining the manufacturing method of the acoustic wave device in FIG. 20.

FIG. 24 is a fourth diagram for explaining the manufacturing method of the acoustic wave device in FIG. 20.

FIG. 25 is a fifth diagram for explaining the manufacturing method of the acoustic wave device in FIG. 20.

FIG. 26 is a sixth diagram for explaining the manufacturing method of the acoustic wave device in FIG. 20.

FIG. 27 is a seventh diagram for explaining the manufacturing method of the acoustic wave device in FIG. 20.

FIG. 28 is an eighth diagram for explaining the manufacturing method of the acoustic wave device in FIG. 20.

FIG. 29 is a ninth diagram for explaining the manufacturing method of the acoustic wave device in FIG. 20.

FIG. 30 is a tenth diagram for explaining the manufacturing method of the acoustic wave device in FIG. 20.

FIG. 31 is a first diagram for explaining a manufacturing method of a second modification of an acoustic wave device according to the second example embodiment of the present invention.

FIG. 32 is a second diagram for explaining the manufacturing method of the second modification of the acoustic wave device according to the second example embodiment of the present invention.

FIG. 33 is a third diagram for explaining the manufacturing method of the second modification of the acoustic wave device according to the second example embodiment of the present invention.

FIG. 34 is a fourth diagram for explaining the manufacturing method of the second modification of the acoustic wave device according to the second example embodiment of the present invention.

FIG. 35 is a fifth diagram for explaining the manufacturing method of the second modification of the acoustic wave device according to the second example embodiment of the present invention.

FIG. 36 is a sixth diagram for explaining the manufacturing method of the second modification of the acoustic wave device according to the second example embodiment of the present invention.

FIG. 37 is a seventh diagram for explaining the manufacturing method of the second modification of the acoustic wave device according to the second example embodiment of the present invention.

FIG. 38 is an eighth diagram for explaining the manufacturing method of a second modification of the acoustic wave device according to the second example embodiment of the present invention.

FIG. 39 is a ninth diagram for explaining the manufacturing method of the second modification of the acoustic wave device according to the second example embodiment of the present invention.

FIG. 40 is a tenth diagram for explaining the manufacturing method of the second modification of the acoustic wave device according to the second example embodiment of the present invention.

FIG. 41 is an eleventh diagram for explaining the manufacturing method of the second modification of the acoustic wave device according to the second example embodiment of the present invention.

### DETAILED DESCRIPTION OF THE EXAMPLE EMBODIMENTS

Acoustic wave elements according to example embodiments of the present invention include, for example, a piezoelectric layer made of lithium niobate or lithium tantalate, and a first electrode and a second electrode facing each other in a direction transverse to the thickness direction of the piezoelectric layer.

An acoustic wave element according to an example embodiment of the present invention uses first thickness-shear mode bulk waves.

In an acoustic wave element according to an example embodiment of the present invention, the first electrode and the second electrode are electrodes adjacent to each other, and d/p is, for example, not greater than about 0.5 where d is the thickness of the piezoelectric layer and p is the center-to-center distance between the first and second electrodes. According to the first and second example embodiments, therefore, the acoustic wave elements can increase in Q factor even when reduced in size.

An acoustic wave element according to an example embodiment of the present invention uses Lamb waves as plate waves and can provide resonance characteristics by Lamb waves.

An acoustic wave element according to an example embodiment of the present invention includes a piezoelectric layer made of, for example, lithium niobate or lithium tantalate, and an upper electrode and a lower electrode that face each other in the thickness direction of the piezoelectric layer with the piezoelectric layer interposed therebetween. The acoustic wave element uses bulk waves.

Hereinafter, the present disclosure is clarified by describing specific example embodiments of the acoustic wave elements with reference to the drawings.

The example embodiments described in the specification are illustrative. Some components of each example embodiment can be substituted or combined with components of another example embodiment.

### First Example Embodiment

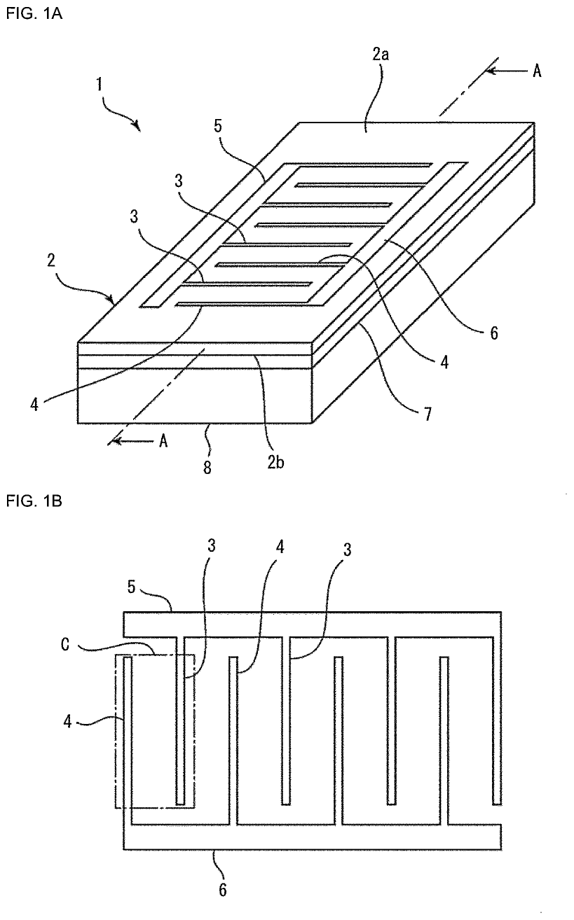

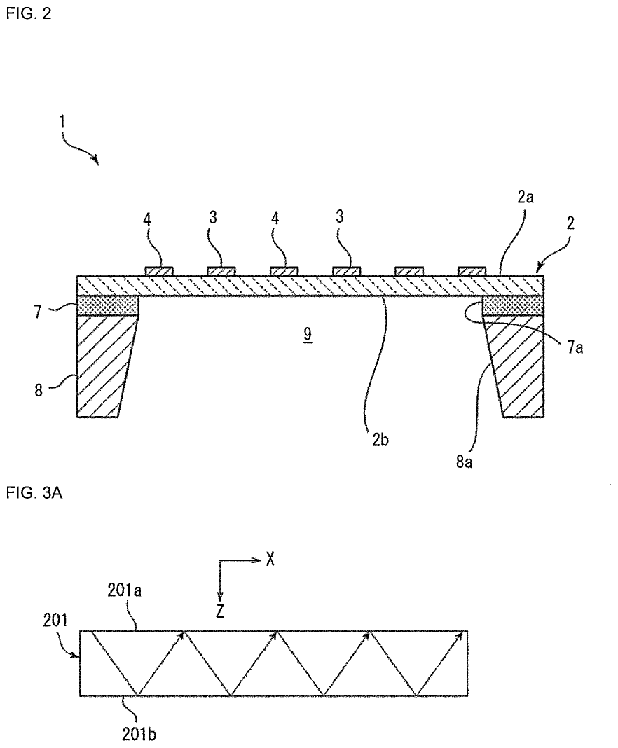

FIG. 1A is a schematic perspective view illustrating an appearance of an acoustic wave element according to a first example embodiment of the present invention. FIG. 1B is a plan view illustrating an electrode structure on the piezoelectric layer. FIG. 2 is a cross-sectional view of a part along line A-A in FIG. 1A.

An acoustic wave element 1 includes a piezoelectric layer 2 made of, for example, LiNbO₃. The piezoelectric layer 2 may be made of, for example, LiTaO₃. In the present example embodiment, the cut angle of LiNbO₃ or LiTaO₃ is set to Z-cut. However, rotated Y-cut or X-cut may be used. Preferably, a preferred propagation orientation is Y-propagation and X-propagation about ±30°. The thickness of the piezoelectric layer 2 is not limited but is preferably, for example, not less than about 50 nm and not greater than about 1000 nm for effective excitation of the first thickness-shear mode.

The piezoelectric layer 2 includes a first major surface 2a and a second major surface 2b, which face each other. On the first major surface 2a, electrodes 3 and electrodes 4 are provided. Herein, the electrodes 3 are an example of the “first electrode”, and the electrodes 4 are an example of the “second electrode”. In FIGS. 1A and 1B, the plural electrodes 3 include plural first electrode fingers coupled to a first busbar 5. The plural electrodes 4 include plural second electrode fingers coupled to a second busbar 6. The plural electrodes 3 are interdigitated with the plural electrodes 4.

The electrodes 3 and 4 each have a rectangular or substantially rectangular shape with a length direction. Each electrode 3 faces the electrode 4 adjacent thereto in a direction perpendicular or substantially perpendicular to the length direction. The plural electrodes 3 and 4, first busbar 5, and second busbar 6 define an interdigital transducer (IDT) electrode. Both of the length direction of the electrodes 3 and 4 and the direction perpendicular or substantially perpendicular to the length direction of the electrodes 3 and 4 are transverse to the thickness direction of the piezoelectric layer 2. That is, each electrode 3 faces the electrode 4 adjacent thereto in a direction transverse to the thickness direction of the piezoelectric layer 2.

The length direction of the electrodes 3 and 4 may be replaced with a direction perpendicular or substantially perpendicular to the length direction of the electrodes 3 and 4 illustrated in FIGS. 1A and 1B. Specifically, the electrodes 3 and 4 may extend in the direction in which the first busbar 5 and the second busbar 6 extend in FIGS. 1A and 1B. In this case, the first busbar 5 and the second busbar 6 extend in the direction in which the electrodes 3 and 4 extend in FIGS. 1A and 1B.

Plural structure pairs each including adjacent electrodes 3 and 4 that are respectively coupled to one potential and the other potential are provided in the direction perpendicular or substantially perpendicular to the length direction of the electrodes 3 and 4. Herein, the adjacent electrodes 3 and 4 refer to electrodes 3 and 4 that are disposed with a space interposed therebetween, but not to electrodes 3 and 4 that are disposed in direct contact with each other.

When the electrodes 3 and 4 are adjacent to each other, any electrode that is coupled to a hot or ground electrode, including the other electrodes 3 and 4, is not disposed between the electrodes 3 and 4. The number of pairs of electrodes 3 and 4 is not necessarily a whole number and may be 1.5, 2.5, or the like. The center-to-center distance between electrodes 3 and 4, that is, the pitch of the same is preferably, for example, not less than about 1 μm and not greater than about 10 μm. The center-to-center distance between electrodes 3 and 4 refers to the distance between the center of the width dimension of the electrode 3 in the direction perpendicular or substantially perpendicular to the length direction of the electrode 3 and the center of the width dimension of the electrode 4 in the direction perpendicular or substantially perpendicular to the length direction of the electrode 4. Furthermore, either the electrode 3 or the electrode 4, or both, include plural electrodes (when the number of electrode pairs is 1.5 or more, each electrode pair including electrodes 3 and 4), the center-to-center distance between electrodes 3 and 4 refers to the average of the center-to-center distances between adjacent electrodes 3 and 4 of the 1.5 or more pairs of electrodes 3 and 4. The width of electrodes 3 and 4, that is, the dimension of the electrodes 3 and 4 in the direction where the electrodes 3 and 4 face each other is preferably, for example, not less than about 150 nm and not greater than about 1000 nm.

In the first example embodiment, since the piezoelectric layer is Z-cut, the direction perpendicular or substantially perpendicular to the length direction of the electrodes 3 and 4 is the direction perpendicular or substantially perpendicular to the polarization direction of the piezoelectric layer 2, except when the piezoelectric layer 2 includes a piezoelectric substance with another cut angle. Herein, “being perpendicular” is not limited to only “being exactly perpendicular” and may include “being substantially perpendicular (the angle between the direction perpendicular to the length direction of the electrodes 3 and 4 and the polarization direction may be, for example, about 90°±10°)”.

On the second major surface 2b side of the piezoelectric layer 2, a support 8 is provided with an insulating layer (also referred to as a bonding layer) 7 interposed therebetween. The insulating layer 7 and the support 8 are frame-shaped and include cavities 7a and 8a as illustrated in FIG. 2. The cavities 7a and 8a define an air gap 9. The air gap 9 is provided not to impede vibration in an excitation region C of the piezoelectric layer 2. The support 8 is provided on the second major surface 2b with the insulating layer 7 interposed therebetween in a position so as not to overlap a portion where at least one pair of electrodes 3 and 4 is provided. The insulating layer 7 is not necessarily provided. The support 8 can therefore be provided directly or indirectly on the second major surface 2b of the piezoelectric layer 2.

The insulating layer 7 is made of, for example, silicon oxide. In addition to silicon oxide, the insulating layer 7 can be made of a proper insulating material, such as, for example, silicon oxynitride or alumina. The support 8 is made of, for example, Si. The plane orientation of Si in the surface close to the piezoelectric layer 2 may be (100), (110), or (111). Preferably, the support 8 is made of, for example, high-resistance Si with a resistivity of not less than about 4 kΩ. The support 8 can be made of an insulating material or a semiconductor material. Examples of the material of the support 8 can include piezoelectric substances, such as aluminum oxide, lithium tantalate, lithium niobate, and quartz crystal, various ceramics, such as alumina, magnesia, sapphire, silicon nitride, aluminum nitride, silicon carbide, zirconia, cordierite, mullite, steatite, and forsterite, dielectrics, such as diamond and glass, and semiconductors, such as gallium nitride.

The above-described plural electrodes 3 and 4, first busbar 5, and second busbar 6 are made of a metal or alloy, such as, for example, Al or AlCu alloy. In the first example embodiment, the plural electrodes 3 and 4, first busbar 5, and second busbar 6 each include an Al film provided on a Ti film, for example. The plural electrodes 3 and 4, first busbar 5, and second busbar 6 may 6 may include an adhesion layer other than Ti film.

To drive the acoustic wave element 1, alternating-current voltage is applied across the plural electrodes 3 and the plural electrodes 4. To be more specific, alternating-current voltage is applied across the first busbar 5 and the second busbar 6. This can provide resonance characteristics using first thickness-shear mode bulk waves excited in the piezoelectric layer 2.

In the acoustic wave element 1, furthermore, d/p is, for example, not greater than 0.5 where d is the thickness of the piezoelectric layer 2 and p is the center-to-center distance between any adjacent electrodes 3 and 4 of the plural pairs of electrodes 3 and 4. The first thickness-shear mode bulk waves can therefore be excited effectively, thus providing good resonance characteristics. More preferably, for example, d/p is not greater than about 0.24. This can provide much better resonance characteristics.

When either the electrode 3 or the electrode 4, or both, include plural electrodes as in the first example embodiment, that is, when the acoustic wave element 1 includes 1.5 or more electrode pairs, where an electrode 3 and an electrode 4 define a pair, the center-to-center distance p between adjacent electrodes 3 and 4 refers to the average of the center-to-center distances between the adjacent electrodes 3 and 4.

In the acoustic wave element 1 of the first example embodiment, due to the above-described configuration, the Q factor is less likely to decrease even when the number of pairs of electrodes 3 and 4 is reduced for size reduction. This is because the configuration defines a resonator not requiring reflectors on both sides and produces a very small propagation loss. The reflectors are not required because the acoustic wave element 1 uses first thickness-shear mode bulk waves.

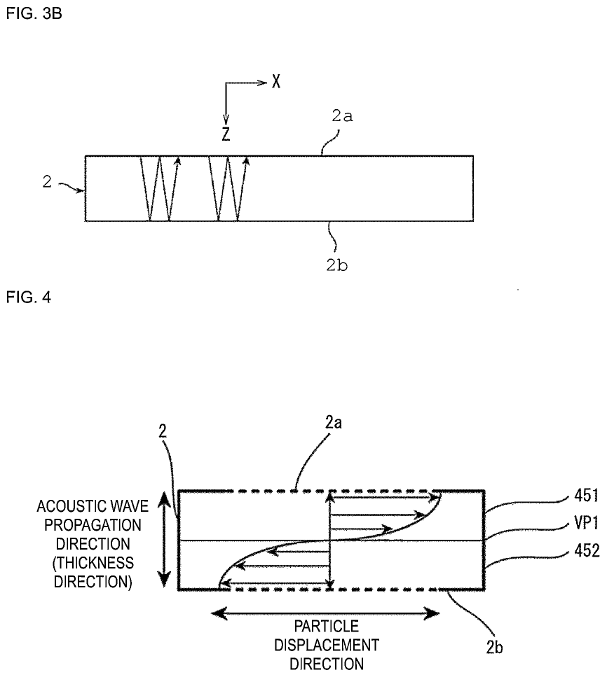

The difference between Lamb waves used in an acoustic wave element in the related art and the first thickness-shear mode bulk waves will be described with reference to FIGS. 3A and 3B.

FIG. 3A is a schematic elevational cross-sectional view for explaining Lamb waves propagating in the piezoelectric film of an acoustic wave element in the related art. The acoustic wave element in the related art is described in Japanese Unexamined Patent Application Publication No. 2012-257019, for example. As illustrated in FIG. 3A, in the conventional acoustic wave element, waves propagate in a piezoelectric film 201 as indicated by arrows. Herein, in the piezoelectric film 201, a first major surface 201a and a second major surface 201b face each other, and the thickness direction that couples the first major surface 201a to the second major surface 201b is Z direction. X direction is the direction where the electrode fingers of the IDT electrode are arranged. As illustrated in FIG. 3A, Lamb waves propagate in the X direction. Since Lamb waves are plate waves, the entire piezoelectric film 201 vibrates, but the waves propagate in the X direction. The resonance characteristics are obtained by providing reflectors on both sides. This produces a wave propagation loss. When the acoustic wave element is reduced in size, that is, when the number of pairs of electrode fingers is reduced, therefore, the Q factor decreases.

As illustrated in FIG. 3B, in the acoustic wave element 1 of the first example embodiment, the displacement of vibration is in the thickness-shear direction, and most waves propagate in the direction that couples the first major surface 2a of the piezoelectric layer 2 to the second major surface 2b, that is, in the Z direction to resonate. This means that the wave component in the X direction is significantly smaller than the wave component in the Z direction. This wave propagation in the Z direction provides resonance characteristics, to eliminate the need for reflectors. The propagation loss due to propagation to reflectors is therefore not produced. The Q factor is therefore less likely to decrease even when the number of electrode pairs each including electrodes 3 and 4 is reduced for size reduction.

As illustrated in FIG. 4, the amplitude direction of first thickness-shear mode bulk waves in a first region 451 included in the excitation region C of the piezoelectric layer 2 is opposite to that in a second region 452 included in the excitation region C of the piezoelectric layer 2. FIG. 4 schematically illustrates bulk waves when voltage is applied across the electrodes 3 and the electrodes 4 such that the potential of the electrodes 4 is higher than that of the electrodes 3. The first region 451 is a region between a virtual plane VP1 and the first major surface 2a in the excitation region C. The virtual plane VP1 is perpendicular or substantially perpendicular to the thickness direction of the piezoelectric layer 2 and divides the piezoelectric layer 2 into two. The second region 452 is a region between the virtual plane VP1 and the second major surface 2b in the excitation region C.

As described above, in the acoustic wave element 1, at least one electrode pair including electrodes 3 and 4 is provided, but waves do not propagate in the X direction. The number of electrode pairs each including electrodes 3 and 4 therefore does not need to be greater than 1. That is, the acoustic wave element 1 only needs to include at least one pair of electrodes.

For example, the electrodes 3 are electrodes coupled to the hot potential while the electrodes 4 are electrodes coupled to the ground potential. However, the electrodes 3 may be coupled to the ground potential while the electrodes 4 are coupled to the hot potential. In the first example embodiment, at least one electrode pair includes an electrode coupled to the hot potential and an electrode coupled to the ground potential as described above, and no floating electrode is provided.

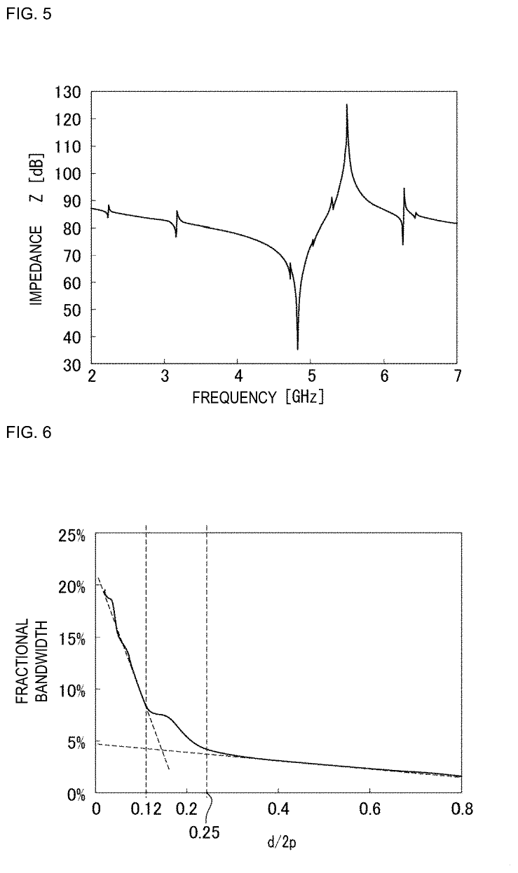

FIG. 5 is a diagram illustrating the resonance characteristics of the acoustic wave element of the first example embodiment of the present invention. The design parameters of the acoustic wave element 1 having these resonance characteristics are as follows.
Piezoelectric layer 2: LiNbO₃ with Euler angles (0°, 0°, 90°), the thickness=about 400 nm

The length of the region where the electrodes 3 and 4 overlap each other as seen in the direction perpendicular to the length direction of the electrodes 3 and 4, that is, the length of the excitation region C=about 40 μm, the number of electrode pairs including the electrodes 3 and 4=21, the center-to-center distance between electrodes=about 3 μm, the width of the electrodes 3 and 4=about 500 nm, and d/p=about 0.133
Insulating layer 7: about 1 μm-thick silicon oxide film
Support 8: Si

The length of the excitation region C is the dimension of the excitation region C in the length direction of the electrodes 3 and 4.

In the first example embodiment, the electrode-to-electrode distance in all of the electrode pairs each including electrodes 3 and 4 is equal or substantially equal. That is, the electrodes 3 and the electrodes 4 are disposed at equal or substantially equal pitch.

As can be seen in FIG. 5, the acoustic wave element 1 has good resonance characteristics with a fractional bandwidth of about 12.5% despite not including reflectors.

As described above, for example, d/p is not greater than about 0.5 and more preferably not greater than about 0.24 in the first example embodiment where d is the thickness of the piezoelectric layer 2 and p is the center-to-center distance between electrodes 3 and 4. This will be described with reference to FIG. 6.

By varying d/2p, multiple acoustic wave elements were created in the same or similar manner to the acoustic wave element having the resonance characteristics illustrated in FIG. 5. FIG. 6 is a diagram illustrating the relationship between this d/2p and the fractional bandwidth of each acoustic wave element as a resonator.

As can be seen in FIG. 6, when d/2p is greater than about 0.25, that is, when d/p>about 0.5, the fractional bandwidth is less than about 5% even if d/p is adjusted. When d/2p≤ about 0.25 on the other hand, that is, when d/p≤ about 0.5, the fractional bandwidth can be about 5% or higher by changing d/p within that range, and it is possible to create a resonator having a high coupling coefficient. When d/2p is not greater than about 0.12, that is, when d/p is not greater than about 0.24, the fractional bandwidth can be increased to about 7% or higher. In addition, when d/p is adjusted within this range, it is possible to create a resonator with a wider fractional bandwidth, that is, it is possible to provide a resonator having a higher coupling coefficient. This reveals that when d/p is set not greater than about 0.5, it is possible to provide a resonator that uses first thickness-shear mode bulk waves and has a high coupling coefficient.

As described above, the at least one electrode pair may include only one electrode pair, and when the at least one electrode pair includes one electrode pair, p described above is the center-to-center distance between the adjacent electrodes 3 and 4. When the at least one electrode pair includes 1.5 or more electrode pairs, p is the average of the center-to-center distances between adjacent electrodes 3 and 4.

When the piezoelectric layer 2 varies in thickness, the thickness d of the piezoelectric layer can be calculated as an average of the thickness of the piezoelectric layer 2.

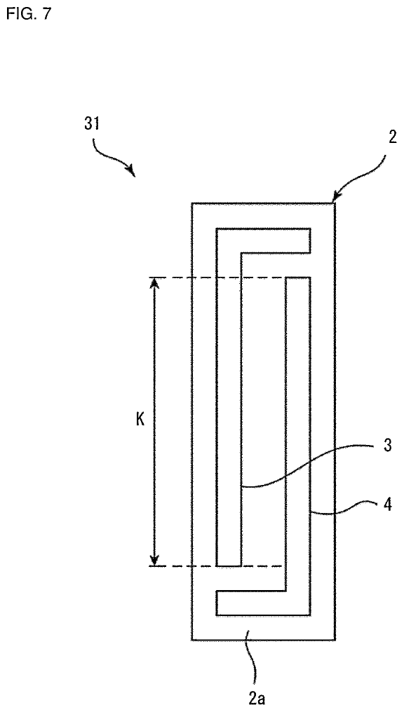

FIG. 7 is a plan view of another acoustic wave element according to the first example embodiment of the present invention. In an acoustic wave element 31, an electrode pair including an electrode 3 and an electrode 4 is provided on the first major surface 2a of the piezoelectric layer 2. K in FIG. 7 indicates an overlap width. As described above, in the acoustic wave element 31 of the present example embodiment, the number of electrode pairs may be one. Even in this case, first thickness-shear mode bulk waves can be effectively excited when d/p described above is not greater than about 0.5.

In the acoustic wave element 1, preferably, for example, a metallization ratio MR satisfies: MR≤ about 1.75(d/p)+0.075 where the metallization ratio MR is a metallization ratio of any adjacent electrodes 3 and 4 of the plural electrodes 3 and 4 to the excitation region, which is the region where the adjacent electrodes 3 and 4 overlap each other as seen in the direction where the electrodes 3 and 4 face each other. In other words, for example, a metallization ratio MR preferably satisfies: MR≤ about 1.75(d/p)+0.075 where the metallization ratio MR is a metallization ratio of plural first electrode fingers and plural second electrode fingers to an excitation region (an overlap region), which is the region where the adjacent plural first and second electrode fingers overlap each other as seen in the direction where the adjacent plural first and second electrode fingers face each other. In this case, spurious components can be effectively reduced or prevented.

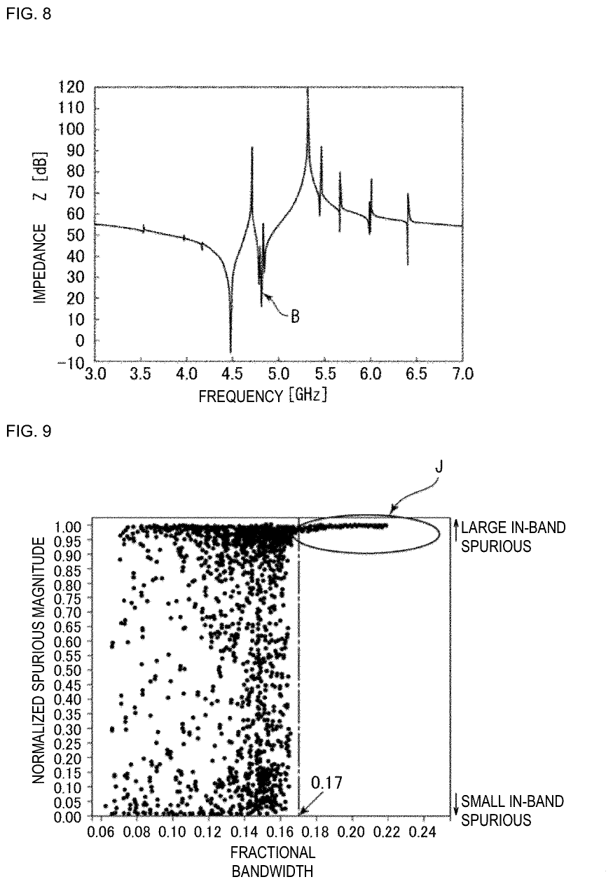

This will be described with reference to FIGS. 8 and 9. FIG. 8 is a reference diagram illustrating an example of resonance characteristics of the acoustic wave element 1. Spurious components indicated by an arrow B appear between the resonant frequency and the anti-resonant frequency. Herein, d/p was set to about 0.08, and Euler angles of LiNbO₃ was set to (0°, 0°, 90°). The above-described metallization ratio MR was set to about 0.35.

The metallization ratio MR will be described with reference to FIG. 1B. Focusing on a pair of electrodes 3 and 4 in the electrode structure of FIG. 1B, it is assumed that only this pair of electrodes 3 and 4 is provided. In this case, the portion surrounded by the dashed-dotted line C is the excitation region. This excitation region includes a region of the electrode 3 overlapping the electrode 4 as the electrodes 3 and 4 are seen in the direction perpendicular or substantially perpendicular to the length direction of the electrodes 3 and 4, that is, in the direction where the electrodes 3 and 4 face each other, a region of the electrode 4 overlapping the electrode 3, and a region where the electrodes 3 and 4 overlap each other in the region between the electrode 3 and the electrode 4. The metallization ratio MR is the area of the electrodes 3 and 4 in the excitation region C with respect to the area of the excitation region C. That is, the metallization ratio MR is the ratio of the area of the metallized part to the area of the excitation region.

When the electrode structure includes plural pairs of electrodes, MR can be a ratio of metallized portion included in all of the excitation regions to the total area of the excitation regions.

FIG. 9 is a diagram illustrating the relationship between the fractional bandwidth and the amount of phase rotation of spurious impedance, which is normalized by about 180 degrees, as the magnitude of spurious components, when many acoustic wave resonators are provided according to the first example embodiment. The fractional bandwidth was adjusted by variously changing the thickness of the piezoelectric layer and the dimensions of the electrodes. FIG. 9 is the result when the piezoelectric layer was made of Z-cut LiNbO₃. Piezoelectric layers with another cut angle have the same tendency.

In the region surrounded by an ellipse J in FIG. 9, the magnitude of spurious components is as large as about 1.0. As can be seen in FIG. 9, when the fractional bandwidth is greater than about 0.17, that is, greater than about 17%, large spurious components with a spurious level of not less than about 1 appear in the pass band even if the parameters of the fractional bandwidth are changed. Similar to the resonance characteristics illustrated in FIG. 8, large spurious components indicated by the arrow B appear in the band. It is therefore preferable that the fractional bandwidth is, for example, not greater than about 17%. In this case, spurious components can be reduced by adjusting the film thickness of the piezoelectric layer 2, dimensions of the electrodes 3 and 4, and the like.

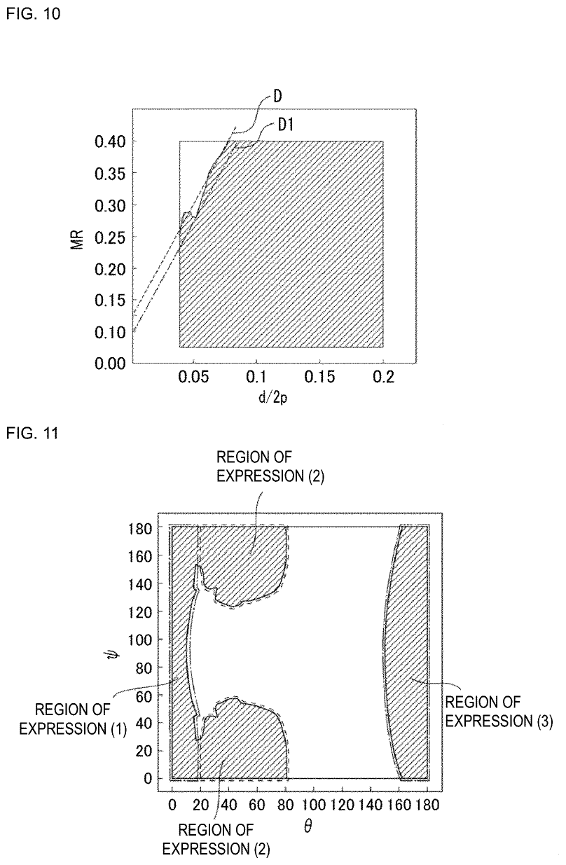

FIG. 10 is a diagram illustrating the relationship between d/2p, the metallization ratio MR, and the fractional bandwidth. Various acoustic wave elements having different values of d/2p and MR were formed according to the aforementioned acoustic wave element, and the fractional bandwidth thereof was measured. The hatched portion to the right of a dashed line D in FIG. 10 is a region in which the fractional bandwidth is not greater than about 17%. The boundary between the region with hatching and the region without hatching is represented by MR=about 3.5(d/2p)+0.075, that is, MR=about 1.75(d/p)+0.075. It is therefore preferable that, for example, MR≤ about 1.75(d/p)+0.075. In this case, the fractional bandwidth can easily be not greater than about 17%. The region to the right of MR=about 3.5(d/2p)+0.05 indicated by a dotted-dashed line D1 in FIG. 10 is more preferable. That is, when MR≤1.75(d/p)+0.05, the fractional bandwidth can be reliably equal to or less than about 17%.

FIG. 11 is a diagram illustrating a fractional bandwidth map with respect to Euler angles (0°, θ, ψ) of LiNbO₃ when d/p is reduced infinitesimally close to zero. Hatched portions in FIG. 11 are regions where the fractional bandwidth is at least not less than 5%. The ranges of the regions are approximated to the ranges expressed by Expressions (1), (2), and (3) below.

(0°±10°,0° to 20°,any ψ) Expression (1)

(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2)

(0°±10°,[180°−30°(1−(ψ−90)²/8100)^{1/2}] to 180°,any ψ) Expression (3)

It is therefore preferable that the Euler angles are within the range expressed by Expression (1), (2), or (3) so that the fractional bandwidth can be widened sufficiently.

FIG. 12 is a partially-cutaway perspective view for explaining an acoustic wave element according to the first example embodiment of the present invention. An acoustic wave element 81 includes a support substrate 82. The support substrate 82 includes a recess opened in the top surface. On the support substrate 82, a piezoelectric layer 83 is provided. The air gap 9 is thus provided. An IDT electrode 84 is provided on the piezoelectric layer 83 above the air gap 9. On both sides of the IDT electrode 84 in the acoustic wave propagation direction, reflectors 85 and 86 are provided. In FIG. 12, a dashed line indicates the outer edge of the air gap 9. The IDT electrode 84 includes a first busbar 84a, a second busbar 84b, plural electrodes 84c as first electrode fingers, and plural electrodes 84d as second electrode fingers. The plural electrodes 84c are coupled to the first busbar 84a. The plural electrodes 84d are coupled to the second busbar 84b. The plural electrodes 84c are interdigitated with the plural electrodes 84d.

In the acoustic wave element 81, applying an alternating-current electric field to the IDT electrode 84 above the air gap 9 excites Lamb waves as plate waves. Since the reflectors 85 and 86 are provided on both sides, the acoustic wave element 81 is able to have resonance characteristics by the Lamb waves.

In such a manner, the acoustic wave element of the present disclosure may use plate waves.

### Second Example Embodiment

An acoustic wave device 100 according to a second example embodiment of the present invention will be described. In the second example embodiment, the description of the contents overlapping the first example embodiment will be omitted. The contents described in the first example embodiment can be applied to the second example embodiment.

As illustrated in FIG. 13, the acoustic wave device 100 includes an acoustic wave element 1, a mounting substrate 140, metal bumps 150, sealing resin 160, and an attenuator 170.

The acoustic wave element 1 includes an element substrate 110, a piezoelectric layer 2, which is provided on the element substrate 110, a functional electrode 120, which is provided on the piezoelectric layer 2, and wiring electrodes 130, which are provided on the piezoelectric layer 2 and are electrically coupled to the functional electrode 120. The element substrate 110 includes an air gap 9 at a position overlapping a portion of the functional electrode 120 in plan view in the stacking direction (the Z direction, for example) of the element substrate 110 and the piezoelectric layer 2. In the second example embodiment, the element substrate 110 includes a support 8 and a bonding layer 7, which is provided on the support 8. The piezoelectric layer 2 is provided on the bonding layer 7. The bonding layer 7 is provided on the support 8 on a side close to the piezoelectric layer 2 in the stacking direction Z. That is, the bonding layer 7 is disposed closer to the piezoelectric layer 2 than the support 8 in the stacking direction Z. The air gap 9 is provided in the bonding layer 7. The functional electrode 120 is positioned between the two wiring electrodes 130 which are provided on the piezoelectric layer 2 and spaced apart from each other in the direction transverse to the stacking direction Z.

The mounting substrate 140 includes external terminals 141, which are disposed facing the respective wiring electrodes 130. The metal bumps 150 are positioned between the respective wiring electrodes 130 and the mounting substrates 140 and couple the wiring electrodes 130 and the external terminals 141. The sealing resin 160 seals the acoustic wave element 1 and the metal bumps 150 so as to surround the acoustic wave element 1 and the metal bumps 150 together with the mounting substrate 140. The attenuator 170 is provided in at least a portion of the outer surface of the element substrate 110, except the surface of contact with the piezoelectric layer 2 (in the second example embodiment, one major surface 1101 close to the piezoelectric layer 2 that faces the piezoelectric layer 2 in the stacking direction Z) to attenuate unwanted emissions.

The attenuator 170 can include any structure that attenuates unwanted emissions. In the second example embodiment, as the attenuator 170, either an inclined surface 171 or protrusions 172, or both are provided in the other major surface 1102 (that is, a bottom surface 801 of the support 8) of the element substrate 110, which is opposite to the one major surface 1101 in the stacking direction Z.

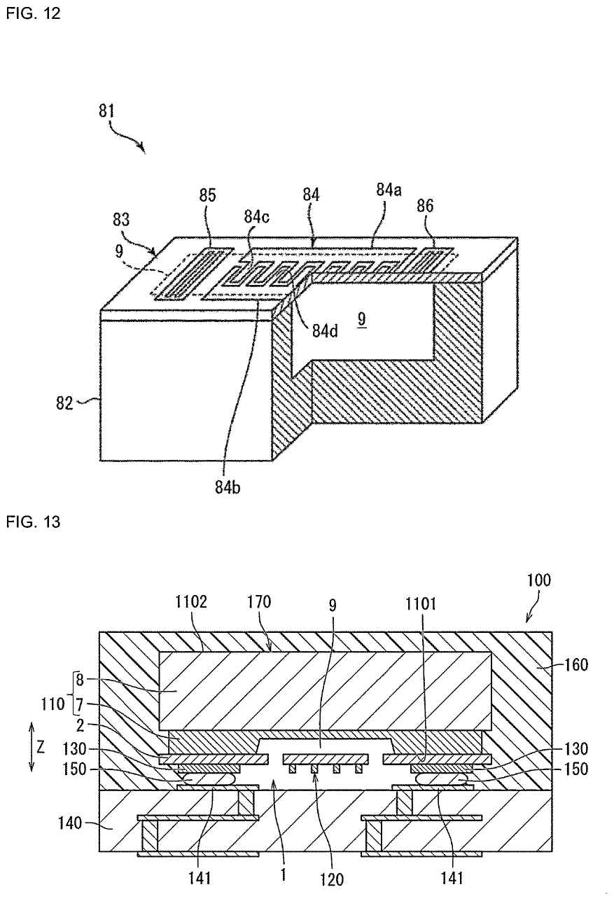

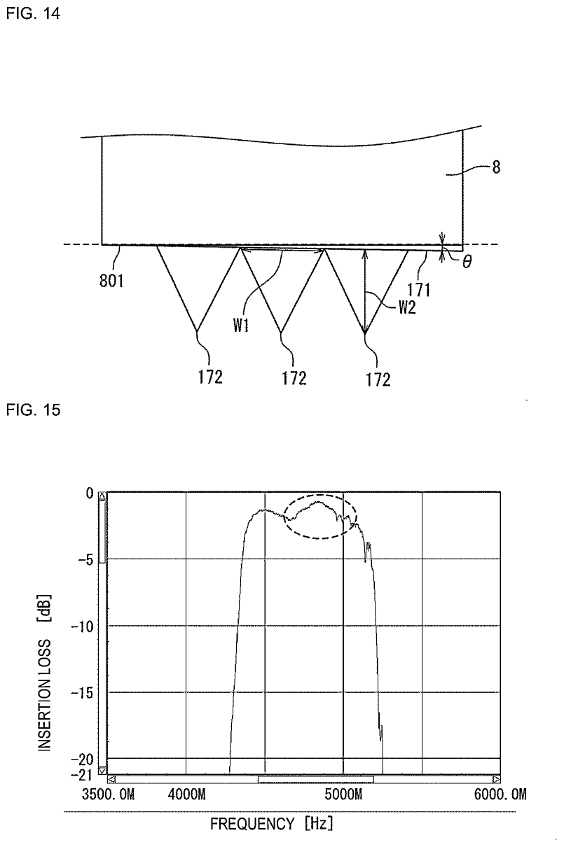

FIG. 14 illustrates an example of the attenuator 170 including both the inclined surface 171 and the protrusions 172. The inclined surface 171 is inclined, for example, at an inclination angle θ of about 1 degree with respect to the one major surface 1101. The protrusions 172 have, for example, a triangular or substantially triangular cross-sectional shape with a bottom dimension W1 of about 3 μm and a height W2 of about 3 μm. In FIG. 14, a virtual line parallel or substantially parallel to the one major surface 1101 is indicated by a dotted line. The protrusions 172 may be made of the same material as the support 8 or may be made of a material different from the support 8. That is, the attenuator 170 may be made of the same material as the element substrate 110 or may be made of a material different from the element substrate 110. The attenuator 170 made of a material different from the element substrate 110 is an example of a different material portion.

The acoustic wave device 100 including the attenuator 170 illustrated in FIG. 14 provides the following results compared to an acoustic wave device not including the attenuator 170. Specifically, the advantageous effect of attenuating unwanted emissions can be provided through either the inclined surface 171 or the protrusions 172 and can be improved through the combination thereof.
When only the inclined surface 171 was provided as the attenuator 170, the unwanted emission reduction rate (the rate of decrease in S11 induced by unwanted emissions of all S11 components) increased by about 12.2%.
When only the protrusions 172 were provided as the attenuator 170 (the attenuator 170 is composed of an uneven surface and the other major surface 1102 is roughened due to the attenuator 170), the unwanted emission reduction rate (the rate of decrease in S11 induced by unwanted emissions of all S11 components) increased by about 33.3%.
When the inclined surface 171 and protrusions 172 were provided as the attenuator 170, the unwanted emission reduction rate (the rate of decrease in S11 induced by unwanted emissions of all S11 components) increased by about 41.6%.

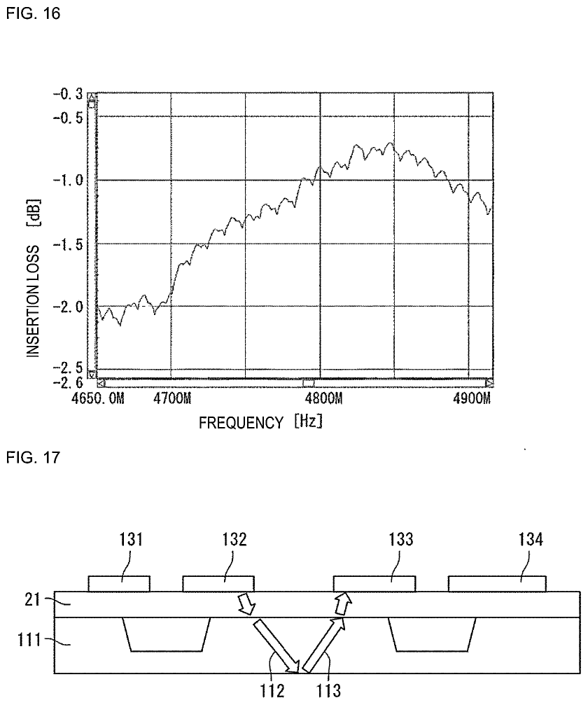

An acoustic wave device not including the attenuator 170, as illustrated in FIGS. 15 and 16, sometimes has a large number of ripples caused in and out of the filter pass band. Superposition of the ripples on an important portion of the filter characteristics significantly deteriorates the filter characteristics.

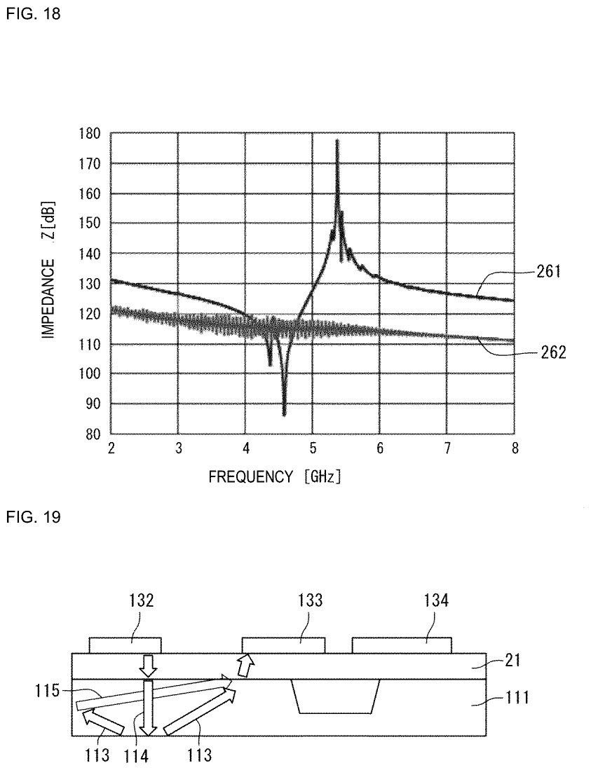

As illustrated in FIGS. 17 and 18, when thickness-shear mode waves are excited in the thin piezoelectric layer 21 between the wiring electrodes (signal lines, for example) 131 and 132 having different potentials, the excited waves leak into the support substrate 111, which includes the bonding layer, and propagate. Thickness-shear mode waves 112 propagated in the support substrate 111 is reflected off the end surface, such as the bottom surface, of the support substrate 111 and is subsequently re-propagated to the piezoelectric layer 21. Thickness-shear mode waves 113 reflected and propagated are converted into spurious signals in the piezoelectric layer 2 and then superposed on signals between the wiring electrodes 133 and 134 having different potentials, thus generating ripples. Due to such a mechanism of ripple generation, the ripple strength therefore tends to be higher when the signal strength is stronger and closer to the input signal and the support substrate 111 is thinner. This is because, qualitatively, the stronger the signal strength and the closer to the input signal, the stronger the excited waves. Furthermore, the thinner the support substrate 111, the shorter the distance of the waves as they are generated, reflected off the end surface of the support substrate 111, and subsequently re-propagated to the piezoelectric layer. In FIG. 18, reference numeral 261 indicates the relationship between impedance Z and frequency in the absence of the support substrate 111, and reference numeral 262 indicates the relationship between impedance Z and the frequency in the presence of the support substrate 111 (for example, about 50 μm thick Si).

As illustrated in FIG. 19, thickness-shear mode waves 114 excited in the thin piezoelectric layer 21 between the wiring electrodes (signal lines, for example) 131 and 132 having different potentials are reflected off the bottom surface of the support substrate 111 and subsequently re-propagated to the piezoelectric layer 21. Thickness-shear mode waves 113 reflected off the bottom surface and propagated are reflected off the side surface of the support substrate 111 and subsequently re-propagated to the piezoelectric layer 21. Thickness-shear mode waves 115 reflected off the side surface and propagated are converted into spurious signals in the piezoelectric layer 21, which are then superposed on signals between the wiring electrodes 133 and 134 having different potentials to sometimes generate ripples.

The way of attenuating ripples is, for example, a method of forming a low acoustic impedance layer in the bottom surface of the support substrate 111 by, for example, laser irradiation or another process or a method of roughening the bottom surface of the support substrate 111 to scatter unwanted emissions. However, using either method will result in acoustic wave elements having low mechanical strength. The resulting acoustic wave elements can be broken in the mounting process and are difficult to handle.

The acoustic wave device 100 of the present example embodiment includes the acoustic wave element 1, the mounting substrate 140, the metal bumps 150, the sealing resin 160, and the attenuator 170 to attenuate unwanted emissions. The acoustic wave element 1 includes the element substrate 110, the piezoelectric layer 2, which is provided on the element substrate 110, the functional electrode 120, which is provided on the piezoelectric layer 2, and the wiring electrodes 130, which are provided on the piezoelectric layer 2 and are electrically coupled to the functional electrode 120. The element substrate 110 includes the air gap 9 at a position overlapping a portion of the functional electrode 120 in plan view in the stacking direction of the element substrate 110 and the piezoelectric layer 2. The mounting substrate 140 includes external terminals 141. The metal bumps 150 couple the wiring electrodes 130 and the external terminals 141. The sealing resin 160 seals the acoustic wave element 1 and the metal bumps 150. The attenuator 170 is provided in at least a portion of the outer surface of the element substrate 110 except the surface of contact with the piezoelectric layer 2 to attenuate unwanted emissions. Encasing the acoustic wave element 1 with the sealing resin 160 can improve the mechanical strength of the entire acoustic wave element 1. Furthermore, providing the attenuator 170 in at least a portion of the outer surface of the element substrate 110 except the surface of contact with the piezoelectric layer 2 can improve the adhesion between the element substrate 110 and the sealing resin 160 while reducing reflection of unwanted emissions off the interface between the element substrate 110 and the sealing resin 160 to attenuate unwanted emissions within the sealing resin 160. This can provide the acoustic wave device 100 that ensures mechanical strength with unwanted emissions attenuated.

The acoustic wave device 100 of the second example embodiment can also be configured as follows.

The element substrate 110 is not limited to the configuration including the support 8 and the bonding layer 7, which is provided on the support 8, and does not need to include the bonding layer 7. In this case, the air gap 9 is provided in, for example, the support 8.

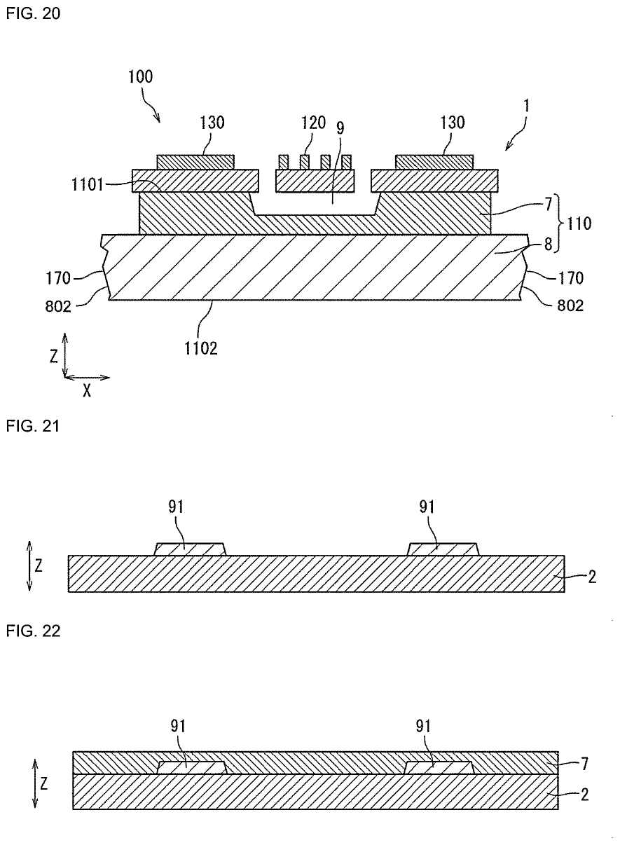

As illustrated in FIG. 20, the attenuator 170 may be provided in the side surface continuing to the sides of the pair of major surfaces 1101 and 1102 of the element substrate 110. In the acoustic wave device 100 in FIG. 20, the attenuator 170 includes an uneven surface and is provided in a side surface 802 of the support 8 extending in the stacking direction Z. The attenuator 170 including an uneven surface is an example of an uneven portion. In the acoustic wave device 100 in FIG. 20, both ends of the bonding layer 7 are positioned closer to the functional electrode 120 than both ends of the piezoelectric layer 2 in a direction (the X direction, for example) transverse to the stacking direction Z. Such a configuration improves the adhesion between the acoustic wave element 1 and the sealing resin 160. FIG. 20 does not illustrate the components of the acoustic wave device 100 other than the acoustic wave element 1 and the attenuator 170.

An example of a manufacturing method of the acoustic wave device 100 in FIG. 20 will be described with reference to FIGS. 21 to 30. The manufacturing method of the acoustic wave device 100 that will be described herein includes a process of forming the air gap 9 by using a sacrificial layer. However, another manufacturing method can be used, such as, for example, a manufacturing method of the acoustic wave device 100 including etching the support 8 and bonding layer 7 from the bottom surface.

As illustrated in FIG. 21, sacrificial layers 91 are formed on the piezoelectric layer 2. The sacrificial layers 91 are formed by, for example, forming a film of a sacrificial layer material on the entire or substantially the entire surface of the piezoelectric layer 2, then performing resist patterning for its surface, and etching the exposed sacrificial layer, followed by removing the resist.

As illustrated in FIG. 22, the bonding layer 7 is formed on the piezoelectric layer 2 on which the sacrificial layers 91 are formed and is then cut to be flattened. The sacrificial layers 91 are thus embedded in the bonding layer 7.

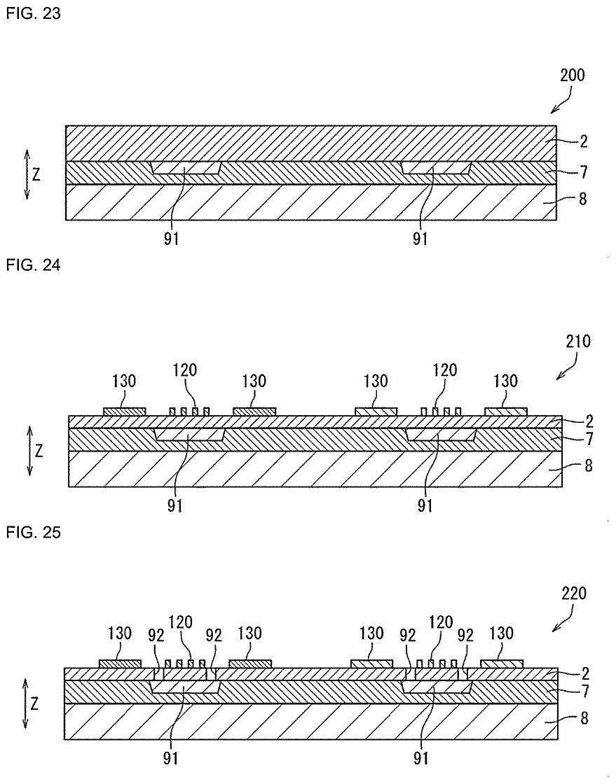

As illustrated in FIG. 23, the support 8 is bonded to the bonding layer 7 in which the sacrificial layers 91 are embedded, thus forming a laminate product 200.

As illustrated in FIG. 24, the piezoelectric layer 2 of the laminate product 200 is cut to be thinned. The functional electrodes 120 and the wiring electrodes 130 are formed on the thinned piezoelectric layer 2 by lift-off, thus forming a laminate product 210.

As illustrated in FIG. 25, holes 92 for removing the sacrificial layers 91 are formed in the piezoelectric layer 2 of the laminate product 210, thus forming a laminate product 220. The holes 92 are formed by, for example, resist patterning, dry etching of the piezoelectric layer, and resist removal.

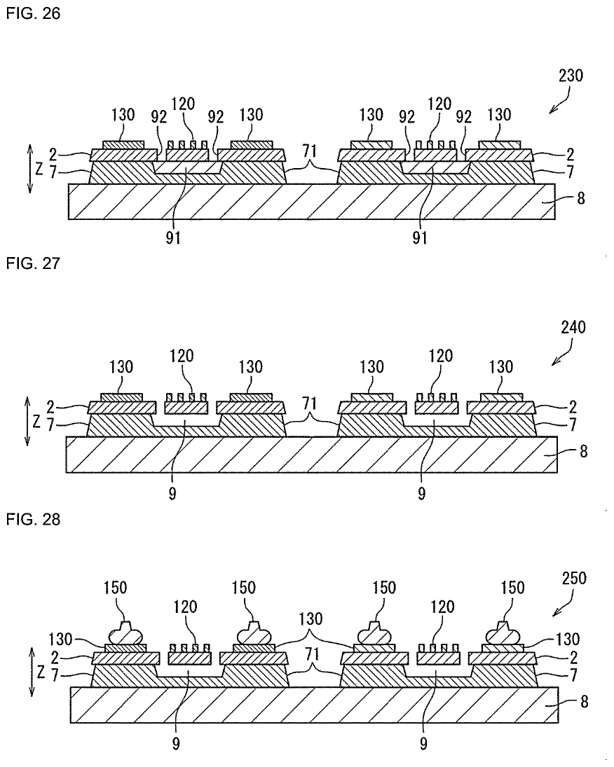

As illustrated in FIG. 26, the piezoelectric layer 2 and the bonding layer 7 are partially removed in dicing a portion of the laminate product 220, thus forming a laminate product 230. The piezoelectric layer 2 and the bonding layer 7 are partially removed in the dicing portion by, for example, resist patterning, dry etching, and resist removal. An inverse-tapered portion 71 is formed in the bonding layer 7 by setting a selectivity in the process of dry etching of the piezoelectric layer 2 and bonding layer 7 such that both ends of the bonding layer 7 can be positioned closer to the functional electrode 120 than both ends of the piezoelectric layer 2 in a direction transverse to the stacking direction Z.

As illustrated in FIG. 27, the air gaps 9 are formed in the laminate product 230, thus forming a laminate product 240. The air gaps 9 are formed by removing the sacrificial layers 91 through, for example, resist patterning, sacrificial layer etching, and resist removal. By forming the air gaps 9, membrane portions are formed in the piezoelectric layer 2.

As illustrated in FIG. 28, the metal bumps 150 are formed on the wiring electrodes 130 of the laminate product 240, thus forming a laminate product 250.

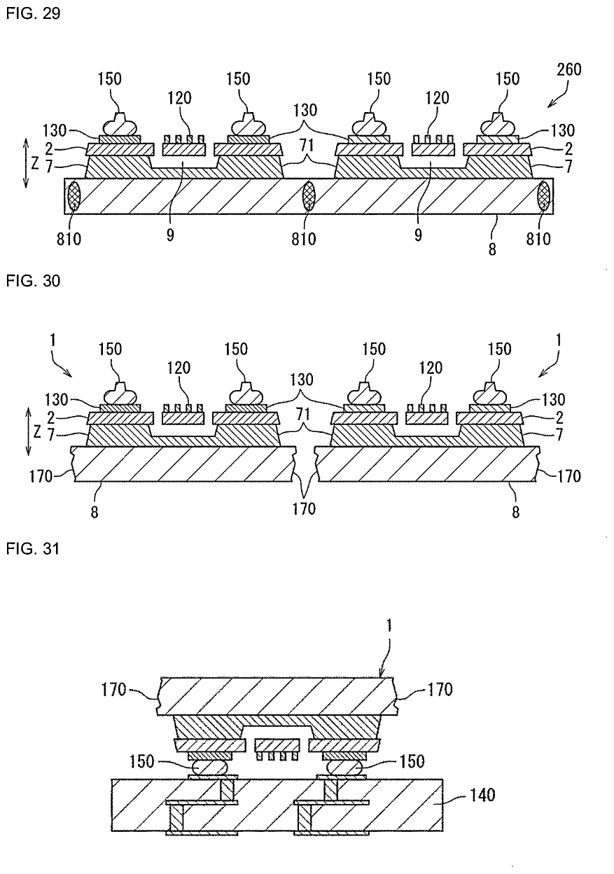

As illustrated in FIG. 29, laser light is projected onto dicing lines of the laminate product 250 to form cleavage portions 810 within the support 8. A laminate product 260 is thus formed.

As illustrated in FIG. 30, the laminate product 260 is cleaved at the cleavage portions 810 to singulate the acoustic wave elements 1 with the metal bumps 150 coupled to the wiring electrodes 130. The portions of the singulated acoustic wave elements 1 where the cleavage portions 810 were formed define the attenuator 170. The singulated acoustic wave elements 1 are coupled to the mounting substrate 140 through the metal bumps 150, and the acoustic wave elements 1 and the metal bumps 150 are sealed with the sealing resin 160. The acoustic wave device 100 is thus formed, and the manufacturing process of the acoustic wave device 100 is completed.

The attenuator 170 may be provided in both of the other major surface 1102 and the side surface of the element substrate 110. An example of the manufacturing method of the acoustic wave device 100 in which the attenuator 170 is provided in the bottom surface 801 and the side surface 802 of the support 8 will be described with reference to FIGS. 31 to 41.

### First Example

As illustrated in FIG. 31, the acoustic wave element 1 illustrated in FIG. 30 in which the metal bumps 150 are coupled to the wiring electrodes 130 is formed and is coupled to the mounting substrate 140 with the metal bumps 150 interposed therebetween. The acoustic wave element 1 is coupled to the mounting substrate 140 by, for example, flip-chip bonding.

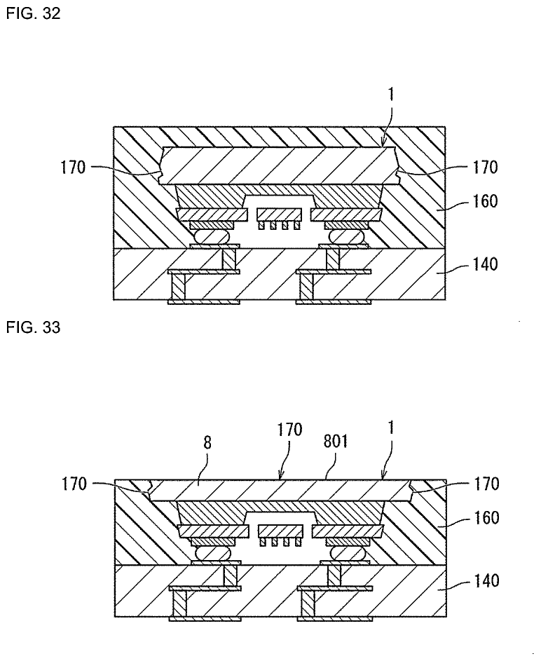

As illustrated in FIG. 32, the acoustic wave element 1 and the metal bumps 150 coupled to the mounting substrate 140 are sealed with the sealing resin 160.

As illustrated in FIG. 33, a portion of the sealing resin 160, which seals the acoustic wave element 1 and metal bumps 150 and which is close to the bottom surface 801 of the support 8, is cut off to expose the bottom surface 801 of the support 8 to the outside. The attenuator 170 is then formed in the bottom surface 801 of the support 8 exposed to the outside. The attenuator 170 is formed by, for example, the following steps. The attenuator 170 including a low acoustic impedance layer is an example of a low acoustic impedance portion.
(A) Forming unevenness in the bottom surface 801 of the support 8 by cutting
(B) Diagonally cutting a part or the entirety of the bottom surface 801 of the support 8
(C) Forming a low-density SiO₂ film on the bottom surface 801 of the support 8 by CVD to form a low acoustic impedance layer
(D) Forming an attenuation layer in the support 8 close to the bottom surface 801 by laser irradiation

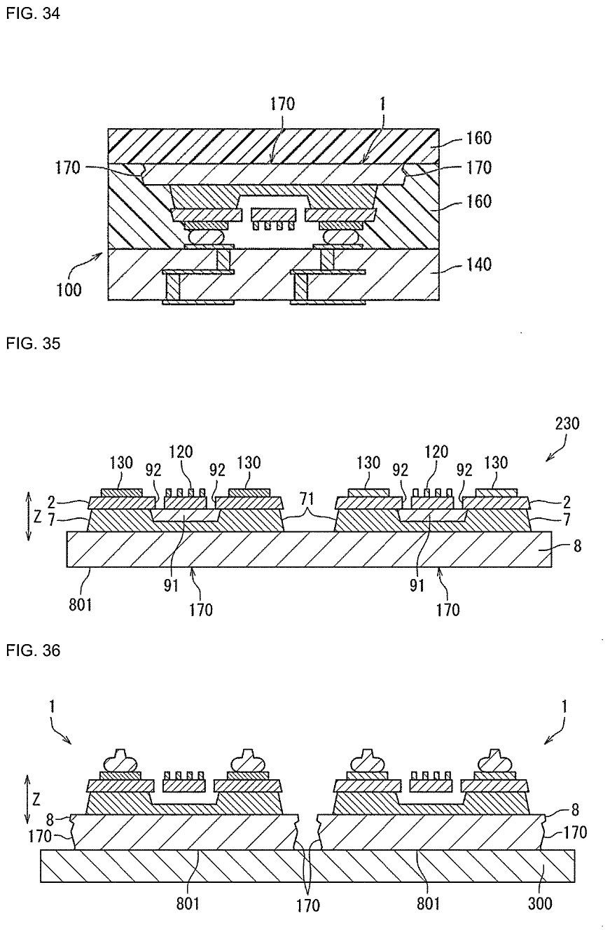

As illustrated in FIG. 34, the bottom surface 801 of the support 8 is sealed with the sealing resin 160, followed dicing for singulation. The acoustic wave device 100 is thus formed, and the manufacturing process of the acoustic wave device 100 is completed. The sealing resin 160 for sealing the bottom surface 801 of the support 8 may be the same material as the first sealing resin 160 (see FIG. 32) or may be a material different from the same. When the attenuator 170 is formed in the bottom surface 801 of the support 8 by the aforementioned steps (A), (C), and (D), the bottom surface 801 of the support 8 does not need to be sealed with the sealing resin 160. That is, the attenuator 170 may be exposed from the sealing resin 160. In this case, it is possible to reduce the manufacturing man-hours of the acoustic wave device 100.

### Second Example

The processes in FIGS. 21 to 26 are executed to form the laminate product 230. As illustrated in FIG. 35, the attenuators 170 are formed in the bottom surface 801 of the support 8 of the formed laminate product 230. The attenuators 170 are formed for the respective acoustic wave elements 1 to be singulated by, for example, the aforementioned steps (A), (C), and (D). The processes in FIGS. 27 to 30 are then executed for the laminate product 230 with the attenuators 170 formed therein to form the acoustic wave device 100. The manufacturing process of the acoustic wave device 100 is thus completed.

### Third Example

The processes in FIGS. 21 to 30 are executed to singulate the acoustic wave elements 1. As illustrated in FIG. 36, the acoustic wave elements 1 are singulated by attaching a dicing tape 300 to the bottom surface 801 of the support 8 of the laminate product 260 and then expanding the dicing tape 300 to cleave the laminate product 260 at the cleavage portions 810.

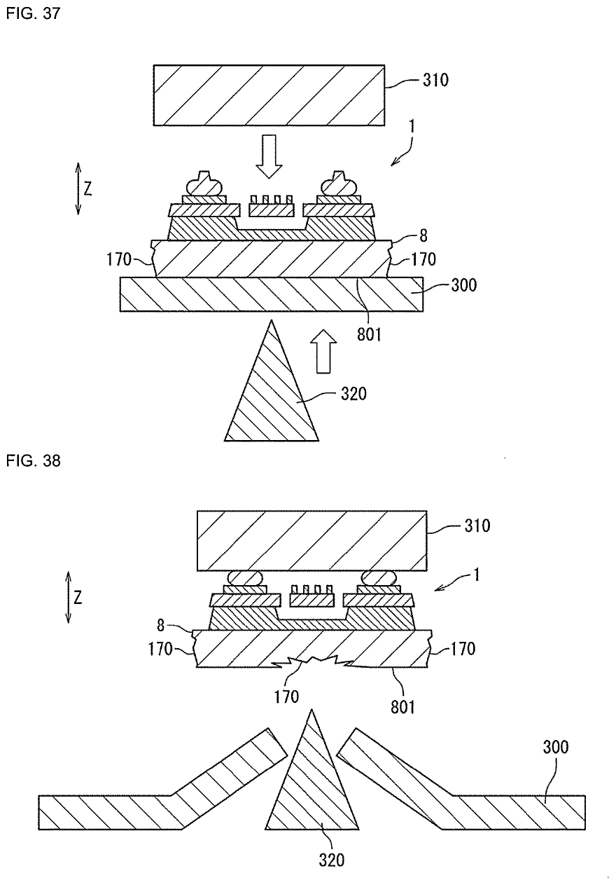

As illustrated in FIG. 37, the singulated acoustic wave elements 1 are picked up from the dicing tape 300. In this process, to facilitate the acoustic wave elements 1 sticking to the nozzle 310, each acoustic wave element 1 is pressed from the back of the dicing tape 300 with a needle 320. At this time, the bottom surface 801 of the support 8 of the acoustic wave element 1 can be scratched by configuring the needle 320 with a specific shape. This forms the attenuator 170 in the bottom surface 801 of the support 8 (see FIG. 38). The scratches formed by the needle 320 have an advantageous effect comparable to roughening of the bottom surface 801.

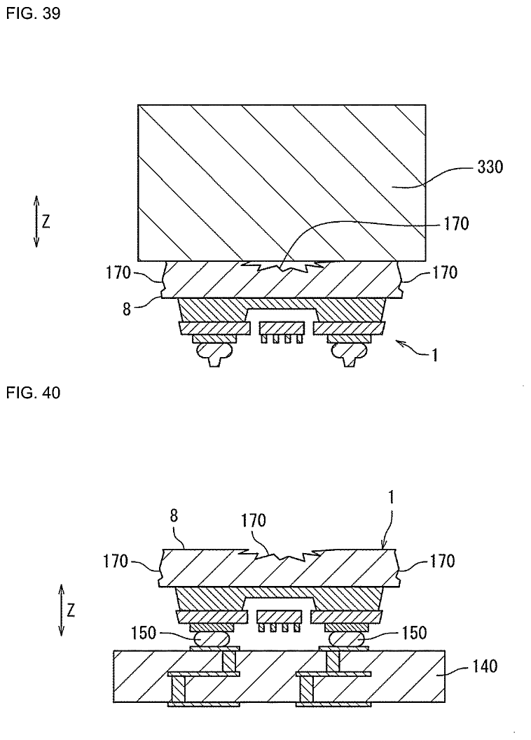

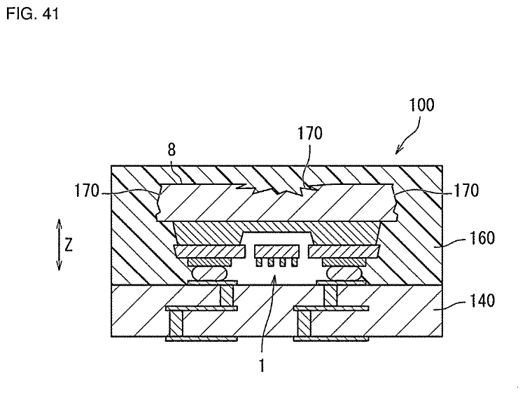

As illustrated in FIG. 39, the singulated acoustic wave element 1 is moved from the nozzle 310 onto a tool 330. Then, as illustrated in FIG. 40, the singulated acoustic wave element 1 is coupled to the mounting substrate 140 with the metal bumps 150 interposed therebetween. The acoustic wave element 1 is coupled to the mounting substrate 140 by, for example, flip-chip bonding. As illustrated in FIG. 41, the acoustic wave element 1 and the metal bumps 150 coupled to the mounting substrate 140 are sealed with the sealing resin 160 to form the acoustic wave device 100. The manufacturing process of the acoustic wave device 100 is thus completed.

The acoustic wave element 1 of the first example embodiment may be included with at least a portion of the configuration of the acoustic wave element 1 of the second example embodiment. The acoustic wave element 1 of the second example embodiment may be included with at least a portion of the configuration of the acoustic wave element 1 of the first example embodiment.

Hereinabove, various example embodiments of the present invention are described in detail with reference to the drawings.

Combinations of any example embodiments, modifications of the example embodiments, and examples provide the same or substantially the same advantageous effects as each example embodiment, each modification, and each example. It is possible to combine example embodiments and combine example embodiments with one another. It is also possible to combine features included in different example embodiments, modifications thereof, or examples.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate includes an air gap at a position overlapping a portion of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
an attenuator in at least a portion of an outer surface of the element substrate, except a surface in contact with the piezoelectric layer, and structured to attenuate unwanted emissions.

2. The acoustic wave device according to claim 1, wherein
the element substrate includes a support and a bonding layer on the support;
the bonding layer is provided on the support on a side adjacent to the piezoelectric layer; and
in the bonding layer, the air gap is provided at a position overlapping a portion of the functional electrode in plan view in the stacking direction.

3. The acoustic wave device according to claim 1, wherein the attenuator is provided in a side surface extending to sides of a pair of major surfaces of the element substrate that are transverse to the stacking direction.

4. The acoustic wave device according to claim 1, wherein the attenuator is provided in, of a pair of major surfaces of the element substrate that are transverse to the stacking direction, another major surface opposite to one major surface adjacent to the piezoelectric layer.

5. An acoustic wave device comprising:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate includes an air gap at a position overlapping a portion of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
a different material portion in at least a portion of an outer surface of the element substrate, except a surface of contact with the piezoelectric layer, and made of a material different from a material of the element substrate.

6. An acoustic wave device comprising:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate is provided with an air gap at a position overlapping a part of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
an uneven portion in at least a portion of an outer surface of the element substrate, except a surface of contact with the piezoelectric layer, and including an uneven surface.

7. An acoustic wave device comprising:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate includes an air gap at a position overlapping a portion of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
a low acoustic impedance portion in at least a portion of an outer surface of the element substrate, except a surface of contact with the piezoelectric layer, and including a low acoustic impedance layer.

8. The acoustic wave device according to claim 1, wherein the attenuator is exposed from the sealing resin.

9. The acoustic wave device according to claim 4, wherein the attenuator includes an inclined surface inclined relative to, of the pair of major surfaces of the element substrate that are transverse to the stacking direction, the one major surface adjacent to the piezoelectric layer.

10. The acoustic wave device according to claim 1, wherein the functional electrode is an IDT electrode.

11. The acoustic wave device according to claim 1, wherein the acoustic wave device is structured to generate plate waves.

12. The acoustic wave device according to claim 1, wherein the acoustic wave device is structured to generate thickness-shear mode bulk waves.

13. The acoustic wave device according to claim 1, wherein the piezoelectric layer is made of lithium niobate or lithium tantalate;
the functional electrode is an IDT electrode;
the IDT electrode includes a first electrode finger and a second electrode finger facing each other in a direction transverse to the stacking direction;
the first electrode finger and the second electrode finger are adjacent to each other; and
d/p is not greater than about 0.5 where d is a thickness of the piezoelectric layer and p is a center-to-center distance between the first electrode finger and the second electrode finger.

14. The acoustic wave device according to claim 13, wherein d/p is not greater than about 0.24.

15. The acoustic wave device according to claim 1, wherein
the functional electrode is an IDT electrode;
the IDT electrode includes a first electrode finger and a second electrode finger facing each other in a direction transverse to the stacking direction;
the first electrode finger and the second electrode finger are adjacent to each other; and
a metallization ratio MR satisfies MR≤ about 1.75(d/p)+0.075
where d is a thickness of the piezoelectric layer, p is a center-to-center distance between the first electrode finger and the second electrode finger, and the metallization ratio MR is a ratio to an area of an excitation region where the first electrode finger and the second electrode finger overlap each other in a direction transverse to the stacking direction, of an area of the first electrode finger and the second electrode finger within the excitation region.

16. The acoustic wave device according to claim 1, wherein
the piezoelectric layer is made of lithium niobate or lithium tantalate; and
Euler angles (φ, θ, ψ) of the lithium niobate or the lithium tantalate are within a range expressed by Expression (1), (2), or (3):
(0°±10°,0° to 20°,any ψ) Expression (1);
(0°±10°,20° to 80°,0° to 60°(1−(θ−50)²/900)^{1/2}) or (0°±10°,20° to 80°,[180°−60°(1−(θ−50)²/900)^{1/2}] to 180°) Expression (2); and
(0°±10°,[180°−30°(1−(ψ−90)²/8100)^{1/2}] to 180°,any ψ) Expression (3).

17. A method of manufacturing an acoustic wave device that includes:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate includes an air gap at a position overlapping a portion of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
an attenuator in at least a portion of an outer surface of the element substrate, except a surface of contact with the piezoelectric layer, and structured to attenuate unwanted emissions, the method comprising:
forming the attenuator within the element substrate by laser irradiation.

18. A method of manufacturing an acoustic wave device that includes:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate includes an air gap at a position overlapping a portion of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
an attenuator in at least a portion of an outer surface of the element substrate, except a surface of contact with the piezoelectric layer, and structured to attenuate unwanted emissions, the method comprising:
forming the attenuator by performing chemical vapor deposition of a SiO₂ film.

19. A method of manufacturing an acoustic wave device that includes:
an acoustic wave element including:
an element substrate;
a piezoelectric layer on the element substrate;
a functional electrode on the piezoelectric layer; and
a wiring electrode on the piezoelectric layer and electrically coupled to the functional electrode, in which the element substrate includes an air gap at a position overlapping a portion of the functional electrode in plan view in a stacking direction of the element substrate and the piezoelectric layer;
a mounting substrate including an external terminal;
a metal bump coupling the wiring electrode and the external terminal;
sealing resin sealing the acoustic wave element and the metal bump; and
an attenuator in at least a portion of an outer surface of the element substrate, except a surface of contact with the piezoelectric layer, and structured to attenuate unwanted emissions, the method comprising:
in a process of flip-chip bonding the acoustic wave element that is singulated, onto the mounting substrate, providing the attenuator in, of a pair of major surfaces of the element substrate that are transverse to the stacking direction, another major surface that is opposite to one major surface adjacent to the piezoelectric layer.
